(19) United States
(12) Patent Application Publication
(10) Pub. No.: US 2007/0111484 A1
(43) Pub. Date: May 17, 2007

(54) Dicing sheet frame

(75) Inventors: Atsushi Komura, Kariya-city (JP); Muneo Tamura, Nagoya-city (JP); Kazuhiko Sugiura, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/600,097

(22) Filed: Nov. 16, 2006

(30) Foreign Application Priority Data
Nov. 16, 2005 (JP) 2005-331211
Oct. 11, 2006 (JP) 2006-277680

(51) Int. Cl. H01L 21/00

(52) U.S. Cl. 438/464

(57) ABSTRACT

A dicing sheet frame, which is used when a semiconductor wafer adhered to a dicing sheet is cut into chips, includes a plurality of frame parts and a connecting device. The plurality of frame parts supports the dicing sheet. The connecting device connects the plurality of frame parts such that the plurality of frame parts has an annular shape.

### CROSS REFERENCE TO RELATED APPLICATION

This application is based on and incorporates herein by reference Japanese Patent Application No. 2005-331211 filed on Nov. 16, 2005 and Japanese Patent Application No. 2006-277680 filed on Oct. 11, 2006.

### BACKGROUND OF THE INVENTION

1. Field of the Invention

The present invention relates to a dicing sheet frame, particularly to the dicing sheet frame, which is used when a semiconductor wafer is attached to a dicing sheet and is cut into chips.

2. Description of Related Art

As shown in FIG. 9A, when a semiconductor wafer W, which includes a semiconductor, such as silicone, is diced by a laser beam, a dicing sheet is usually adhered on a back surface of the wafer W. The above dicing sheet is called a wafer sheet, a dicing film, or an expandable tape. In this specification, the dicing sheet is called tape T. The tape T is usually made of an adhesive resin film on a side which holds the wafer W. Also, a peripheral portion of the tape T is held by an annular frame (dicing sheet frame) in a state where the tape T is expanded (stretched), and is placed on a mounting table.

Then, modified layers are formed inside the wafer W, which is adhered to the surface of the tape T by the laser beam application. After this, as shown in FIG. 9B, a pressure device upwardly presses the tape T from the back surface such that the tape T expands in a horizontal direction. Therefore, the wafer W, which is adhered to the tape T, receives a force that expands the tape T in a radial direction. Thus, cracks start from the modified layers such that the wafer W is divided into a plurality of semiconductor chips CP. This conventional technique is disclosed in, for example, Japanese Unexamined Patent Publication No. 2005-1001 (paragraphs [0057] to [0069] and FIG. 18) corresponding to US2006/0011593A1 and US2005/0202596A1, and in Japanese Unexamined Patent Publication No. 2003-10986 (paragraphs [0062] to [0064], FIGS. 19, and 29-32) corresponding to US6992026B2, US2006/0160331 A1, US2005/0194364A1, US2006/0040473A1, US2005/0189330A1, US2005/0184037A1, US2005/0181581 A1, and US2005/0173387A1.

As shown in FIG. 9B, once the tape T is expanded by the pressure device P, the tape T does not completely go back to its original state even after the tape T is released from the pressure. Thus, as shown in FIG. 9C, there exists a part γ, which does not go back to the original state. Therefore, a tape Ta, which has been processed, remains loose even when the tape Ta is held by the frame 100. Thus, by cutting a peripheral part (shown as a dotted x in FIG. 9C) of a part t, which is not loose, the not-loose part t is separated. Then, the separated tape is remounted on a smaller frame 200 such that the tape t, which is smaller than the tape Ta, can be reutilized.

However, the above reutilization of the tape requires a removing operation for removing the loose part γ from the processed tape Ta (see FIG. 9C), and also a remounting operation for mounting the separated tape t to the other frame 200 (see FIG. 9D). Thus, these operations may disadvantageously reduce operation efficiency.

Also, the smaller frame 200 needs to be prepared in addition to the usual frame 100. This may disadvantageously increase apparatus cost. Therefore, even if a manufacturing cost is reduced by reutilizing the tape, this cost reduction due to the reutilization may not be maximized because of the above removing operation and the remounting operation of the tapes, and the cost increase of the apparatus.

### SUMMARY OF THE INVENTION

The present invention is made in view of the above disadvantages. Thus, it is an objective of the present invention to address at least one of the above disadvantages.

To achieve the objective of the present invention, there is provided a dicing sheet frame, which is used when a semiconductor wafer adhered to a dicing sheet is cut into chips, the dicing sheet frame including a plurality of frame parts and a connecting device. The plurality of frame parts supports the dicing sheet. The connecting device connects the plurality of frame parts such that the plurality of frame parts has an annular shape.

### BRIEF DESCRIPTION OF THE DRAWINGS

The invention, together with additional objectives, features and advantages thereof, will be best understood from the following description, the appended claims and the accompanying drawings in which:

FIG. 1A is a schematic drawing of a frame when the frame is set in a first annular shape according to a first embodiment of the present invention;

FIG. 1B is a schematic drawing of the frame when the frame is set in a second annular shape according to the first embodiment of the present invention;

FIG. 2A is a schematic diagram of a link mechanism of the frame observed from a direction IIA shown in FIG. 1A according to the first embodiment of the present invention;

FIG. 2B is a schematic diagram of the link mechanism of the frame observed from a direction IIB shown in FIG. 1B according to the first embodiment of the present invention;

FIG. 3A is an explanatory diagram of an expansion process by the frame according to the first embodiment showing a state prior to a first expansion;

FIG. 3B is an explanatory diagram of the expansion process by the frame according to the first embodiment showing a state during the first expansion;

FIG. 3C is an explanatory diagram of the expansion process by the frame according to the first embodiment showing a state after the first expansion;

FIG. 3D is an explanatory diagram of the expansion process by the frame according to the first embodiment showing a state prior to transportation to a downstream process;

FIG. 4A is a schematic diagram of a frame when the frame is set in the first annular shape according to a second embodiment of the present invention;

FIG. 4B is a schematic diagram of the frame when the frame is set in the second annular shape according to the second embodiment of the present invention;

FIG. 5A is a schematic diagram of a modification of the frame when the frame is set in the first annular shape according to the second embodiment of the present invention;

FIG. 5B is a schematic diagram of the modification of the frame when the frame is set in the second annular shape according to the second embodiment of the present invention;

FIG. 6A is a schematic diagram showing a fixed state of a frame by a fixing device when the frame is set in the first annular shape according to a third embodiment of the present invention;

FIG. 6B is a schematic diagram showing a released state of the frame by the fixing device when the frame is set in the second annular shape according to the third embodiment of the present invention;

FIG. 7A is a schematic diagram showing a fixed state of a frame by a halving-joint fixing device when the frame is set in a second annular shape according to a fourth embodiment of the present invention;

FIG. 7B is a schematic diagram showing the fixed state of the frame by a bar-joint fixing device when the frame is set in the second annular shape according to the fourth embodiment of the present invention;

FIG. 7C is a schematic diagram showing the fixed state of the frame by a tongue-and-groove-joint fixing device when the frame is set in the second annular shape according to the fourth embodiment of the present invention;

FIG. 7D is a schematic diagram showing a fixed state of the frame by a plate-joint fixing device of the frame when the frame is set in the second annular shape according to the fourth embodiment of the present invention;

FIG. 8A is a plan view of the fixing device of the frame according to the second embodiment of the present invention showing a fixed state of the frame by the fixing device when the frame is set in the second annular shape;

FIG. 8B is a side view of the frame observed from a direction VIIIB shown in FIG. 8A;

FIG. 8C is a sectional view of the frame taken along line VIIIC-VIIIC in FIG. 8B;

FIG. 9A is an explanatory diagram of an expansion process using a conventional frame in a state prior to a first expansion;

FIG. 9B is an explanatory diagram of the expansion process using the conventional frame during the first expansion;

FIG. 9C is an explanatory diagram of the expansion process using the conventional frame when the frame is released from the first expansion; and

FIG. 9D is an explanatory diagram of the expansion process using the conventional frame in a state prior to transportation to a downstream process.

### DETAILED DESCRIPTION OF PREFERRED EMBODIMENTS

Embodiments of the present invention will be described with reference to accompanying drawings. Here, in the embodiment, a dicing sheet frame of the present invention is applied to a frame of an expandable tape used in a laser dicing. The expandable tape is referred as a tape, and the frame that supports the tape is referred as a frame. The tape corresponds to a dicing sheet, and the frame corresponds to a dicing sheet frame of the present invention.

### First Embodiment

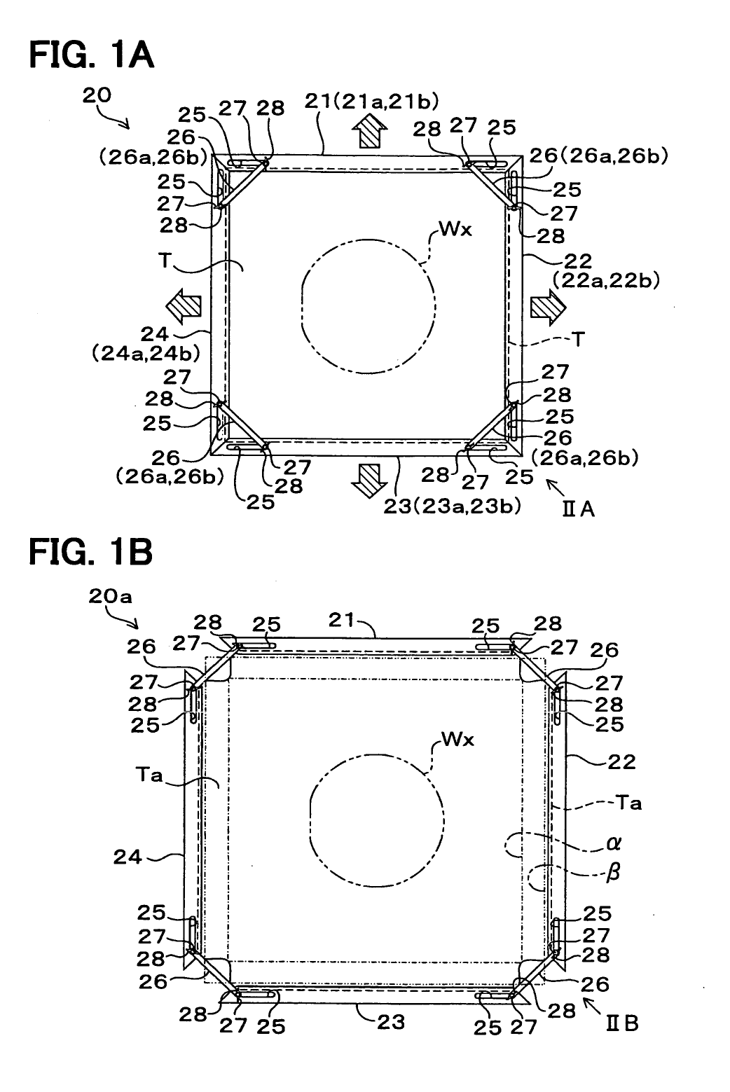

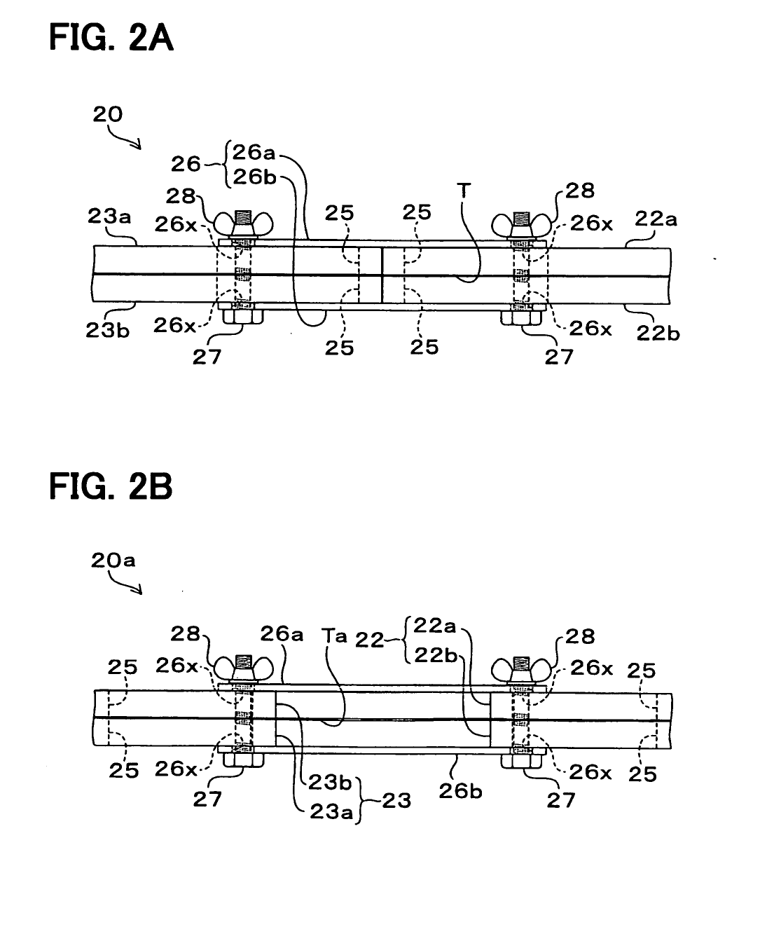

A structure of a frame 20 of the first embodiment will be described with reference to FIGS. 1 and 2. As shown in FIGS. 1A and 1B, the frame 20 is a mount body, which has a generally square annular shape, and mainly includes frame parts 21, 22, 23, 24, links 26, bolts 27, and wingnuts 28. Here, the frame parts 21, 22, 23, 24 correspond to a plurality of frame parts, and the links 26, the bolts 27, and the wingnuts 28, respectively, correspond to a connecting device of the present invention.

Each of the frame parts 21-24 is structured to hold (support) a tape T therebetween, and each of the frame parts 21-24 is structured similar to each other. Thus, the frame part 22 will be described as a representative.

As shown in FIGS. 1A to 2B, the frame part 22 includes a front side frame part 22a, which has a rectangular bar shape, and a back side frame part 22b, which has the rectangular bar shape. The frame part 22 is arranged together with the other frame parts 21, 23, 24 to form the frame 20. The frame parts 21-24 are designed in length such that the frame 20 can surround a wafer position Wx, to which a wafer W is to be adhered.

Each of the front side frame part 22a and the back side frame part 22b is tapered at both ends, each of which has a generally 45 degree. Thus, the front side and back side frame parts 22a, 22b are assembled with the other frame parts 21a, 21b, to form a corner (90 degree) of the square annular frame 20. In other words, each of the front side and back side frame parts 22a, 22b is formed to have a trapezoidal shape as shown in FIG. 1A.

Each of the front side and back side frame parts 22a, 22b has elongated holes 25, which extends in a longitudinal direction, at both end portions thereof. The elongated holes 25 constitute the connecting device of the present invention together with the links 26, the bolts 27 and the wingnuts 28. Thus, each elongated hole 25 has a diameter larger than an axial diameter of the corresponding bolt 27. Also, the elongated hole 25 is designed to have a stroke length such that the frame 20 is displaceable (transformable) from a first annular shape to a second annular shape. Here, the first annular shape corresponds to a state, where the frame 20 is closed by the links 26 as shown in FIG. 1A, and the second annular shape corresponds to a state, where the frame 20 is opened as shown in FIG. 1B.

In the first embodiment, the front side frame part 22a is positioned on a front surface of the tape T. Similarly, the back side frame part 22b is positioned on a back surfaced of the tape T. Therefore, the front side and back side frame parts 22a, 22b have generally similar shapes, and hold both surfaces of the tape T by corresponding facing surfaces of the frame parts 22a, 22b to hold the tape T therebetween. In this case, for example, although this is not illustrated, the front side frame part 22a may have multiple protrusions on its surface, and also the back side frame part 22b may have the corresponding multiple recesses on its surface such that the tape T can be reliably engaged and held between the protrusions and the recesses. Here, the front side and back side frame parts 22a, 22b are fixed together using the links 26 through the bolts 27 and the wingnuts 28 in the first embodiment.

As shown in FIGS. 1A to 2B, each link 26 has a link feature, which includes a front side link 26a and back side link 26b. Here, the front side and back side links 26a, 26b are made of thin bar plates. In the first embodiment, because the frame 20 is structured by the four frame parts 21-24, the front side and back side links 26a, 26b are provided to connect the frame parts 21-24 at four positions such that the frame parts 21-24 form the annular shape.

In other words, each of the front side and back side links 26a, 26b, which constitute the link 26, has holes 26x at both end portions thereof. The corresponding bolt 27 can extends through the hole 26x. The bolts 27, which extend through the holes 26x, fasten the frame parts 21, 22 through the corresponding elongated holes 25 formed at both end portions of the frame parts 21, 22. A group of the frame parts 22, 23, another group of the frame parts 23, 24 and the other group of the frame parts 24, 21 are structured and fastened in the similar way as described above in a case of a group of the frame parts 21, 22. Thus, as shown in FIG. 1A, the frame parts 21-24 are connected to form the square annular shape. Also, as shown in FIG. 1B, the frame parts 21-24 are outwardly displaceable in arrow directions shown in FIG. 1A.

The bolt 27, which constitutes the link mechanism together with the links 26, has substantial longitudinal length to fasten the frame part 21 and the link 26 together. The wingnut 28, which facilitates fastening and loosing the nut, serves as the corresponding nut for the bolt 27.

By designing the frame 20 as the above structure, the frame 20 can be displaceable (transformable) between a closed state and an open state as shown in FIGS. 1A and 1B. Here, in the closed state (the first annular shape state), the frame 20 is closed through the links 26, and in the open state (the second annular shape state), the frame 20 is opened through the links 26. That is, the frame parts 21-24 can be set at the first annular shape (the frame 20 shown in FIG. 1A), which surrounds the wafer position Wx. Here, the first annular shape surrounds a first area α. Also, the frame parts 21-24 can be set at the second annular shape (a frame 20a shown in FIG. 1B), which surrounds a second area β larger than the first area α.

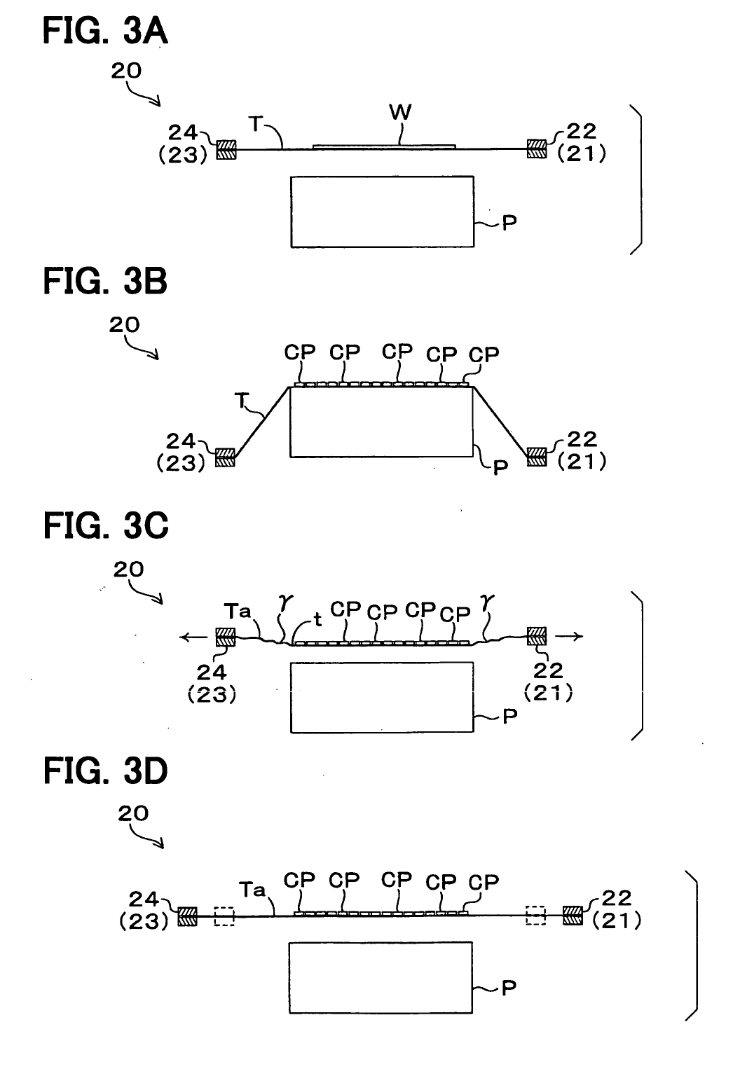

Therefore, when the frame 20 of the first embodiment is used in the expansion process of the wafer W, the following effects and advantages can be achieved. FIG. 3A shows a state prior to the first expansion. The frame 20, which is closed (in the first annular shape state), holds the tape T through the frame parts 21-24 to keep the tape T stretched. In this state, the wafer W is adhered to the surface of the tape T, and the laser beam is applied to the wafer W to form a modified layer inside the wafer W (modification process).

Then, as shown in FIG. 3B, the wafer W is pressed upwardly from the back side of the tape T by a pressure device P for expansion. Therefore, the wafer W, which is adhered to the tape T, receives a force that expands the tape T in a radial direction. Thus, cracks start from the modified layers such that the wafer W is divided into a plurality of semiconductor chips CP (division process).

As shown in FIG. 3C, when the division process of the chips CP is completed, the wafer W (the tape T) is released from the expansion by the pressure device P. Even after the release from the expansion, a tape Ta, which is once stretched or used, cannot completely go back to its original state (a shape of the tape T prior to the use). Thus, a portion γ remains without going back to the original shape. Thus, the frame 20 is transformed by the links 26 from the closed state (the first annular shape state) to the open state (the second annular shape state). This is a frame expansion process. Here, in FIG. 3C, a symbol t indicates a part, which is not loose.

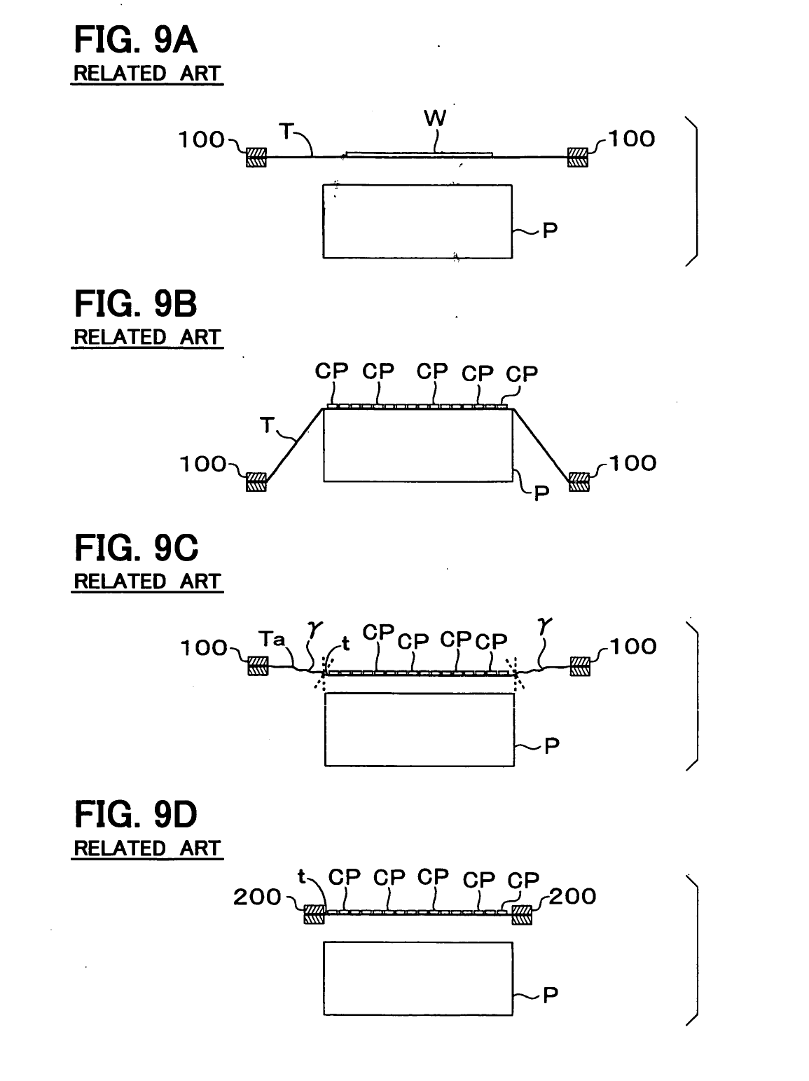

Thus, as shown in FIG. 3D, the utilized (used) tape Ta, which is held by of the frame 20, is expanded or stretched from the first annular shape (FIG. 1A) to the second annular shape (FIG. 1B). Thus, the part γ, which otherwise remains loose and does not go back to the original shape, can be again kept in a stretched state. Here, the first annular shape surrounds the wafer position Wx and corresponds to the first area α, and the second annular shape surrounds the second area β larger than the first area α. Thus, even without a remounting operation for remounting the tape to another frame as shown in FIG. 9D, the multiple chips CP, which are adhered to the tape Ta, can be stably retained. Here, in the remounting operation, the tape Ta is remounted to a frame 200, which has a smaller diameter. This may facilitate a preparation for a downstream process (e.g., a visual inspection process, a die pick up process). Here, in FIG. 3D, rectangular shapes shown by a dotted line indicate frame parts 21-24 in the closed state (the first annular shape state).

Thus, according to the frame 20 of the first embodiment, the link mechanism, which includes the elongated holes 25 of the frame parts 21-24, links 26, bolts 27, and wingnuts 28, connects the frame parts 21-24 in the first annular shape that surrounds the wafer position Wx. Also the link mechanism displaceably connects the frame parts 21-24 such that the frame parts 21-24 can be transformed into the second annular shape, which surrounds the second area β larger than the first area α. In this structure, the tape T is held by the frame parts 21-24. Even when the loose part γ is formed on the utilized tape Ta due to the expansion by the compression in the first annular shape state, the loose part γ can be stretched without remounting the tape Ta to the smaller frame 200 shown in FIG. 9D. This is because the entire of the utilized tape Ta can be stretched outwardly when the frame parts 21-24 are displaced to form the second annular shape. Therefore, the removing operation for removing the loose parts γ described with reference to FIGS. 9C and 9D, and the remounting operation for remounting the tape Ta to the smaller frame 200 can be limited. Thus, the operation efficiency can be improved. Also, because the above smaller frame 200 is not necessary, the apparatus cost can be limited from increasing.

Also, in the frame 20 of the first embodiment, the frame parts 21-24 correspond to four parts, into which the square annular shape is generally equally divided. When the frame parts 21-24 are displaced from the closed state shown in FIG. 1A (the first annular shape state) to the open state shown in FIG. 1B (the second annular shape state), the frame parts 21-24 are radially displaced. This makes it possible to generally equally stretch the entire of the tape T, which is held by the frame parts 21-24. This may limit the tape Ta, which is held by the frame parts 21-24, from becoming wrinkled or twisted after the frame parts 21-24 have been displaced to be the open state (the second annular shape state). Thus, the multiple chips CP can be easily adhered in a state ready for transmission to the downstream process. Therefore, a removing operation for removing the wrinkles or twists is limited from occurring. Thus, the operation efficiency can be improved.

### Second Embodiment

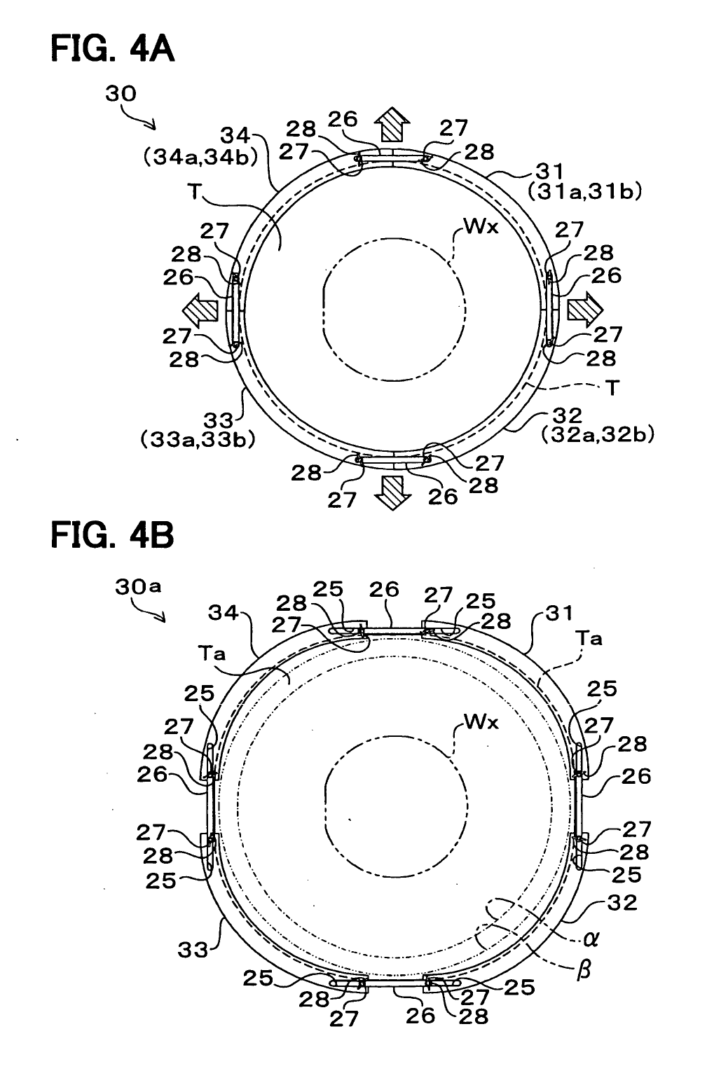

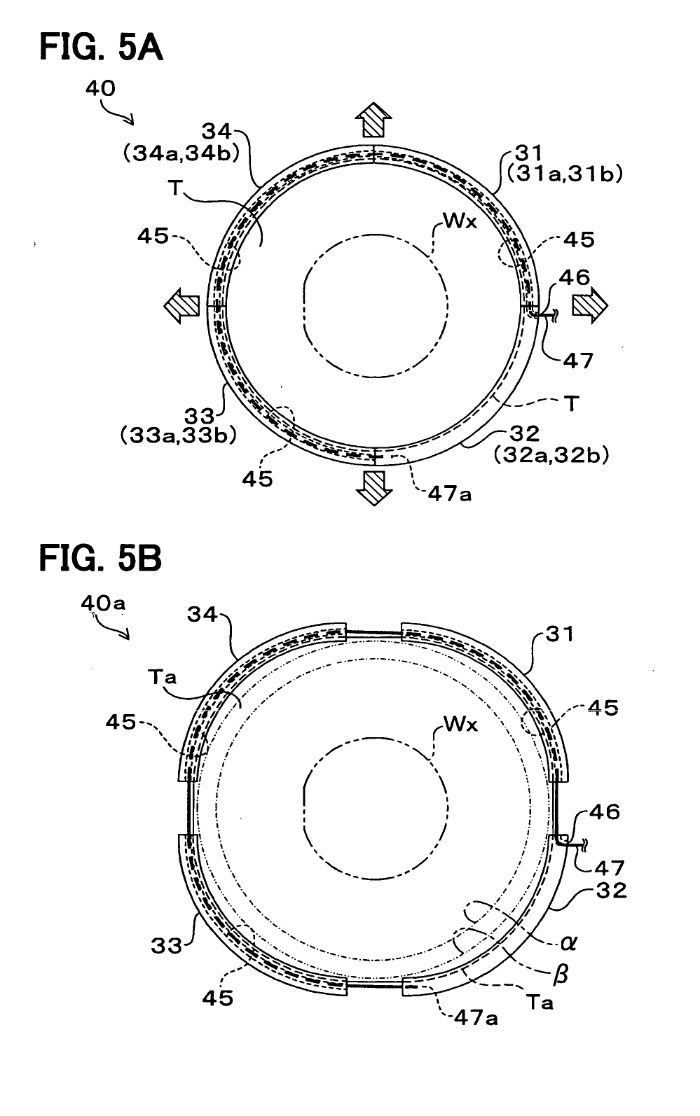

Then, structures of frames 30, 40 of the second embodiment will be described with reference to FIGS. 4 and 5. The frame 30 of the second embodiment is designed to have a generally circular shape. This is different from the frame 20 of the first embodiment, which is designed to have the square annular shape. Therefore, components, which are similar to the components of the above frame 20 of the first embodiment, are indicated by the same numerals and explanation thereof will be omitted.

As shown in FIGS. 4A and 4B, the frame 30 of the second embodiment has the generally circular shape and includes arc frame parts 31, 32, 33, 34 (frame parts 31-34), each of which has a quadrant arc shape. Each of the frame parts 31-34 includes a corresponding front side frame part 31a-34a and a corresponding back side frame part 31b-34b similar to the frame 20 of the first embodiment. Also, the frame parts 31-34 correspond to the plurality of frame parts of the present invention.

In this structure, when the frame parts 31-34 are displaced from the frame 30 to the frame 30a (i.e., when the frame parts 31-34 are displaced from positions corresponding to the frame 30 to other positions corresponding to the frame 30a), the held tape T can be stretched by a better balanced applied force compared with the case of the frame 20 of the first embodiment, in which the frame 20 has the square annular shape (the first annular shape has a rectangular shape). Here, the frame 30 corresponds to the closed state shown in FIG. 4A (the first annular shape state), and the frame 30a corresponds to the open state shown in FIG. 4B (the second annular shape state). This structure may limit the tape Ta, which is held by the frame parts 31-34, from becoming wrinkled or twisted after the frame parts 31-34 have been displaced to be the open state (the second annular shape state). Thus, the multiple chips CP can be easily adhered in a state ready for transmission to the downstream process. Therefore, the removing operation for removing the wrinkles or twists is limited from occurring. Thus, the operation efficiency can be improved.

The frame 40 shown in FIGS. 5A and 5B serves as a modification of the frame 30 of the second embodiment. That is, the frame 40 includes wire passages 45, a wire hole 46, and a connection wire 47 as the connecting device instead of having the link mechanism (elongated holes 25, the links 26, the bolts 27 and the wingnuts 28). The wire passages 45 are formed in the frame parts 31, 33, 34, and the wire hole 46 is formed in the frame part 32. Also, the connection wire 47 is inserted through the wire hole 46 and the wire passages 45 to be fixed to the frame part 32 at an end portion 47a of the connection wire 47. Here, the wire passages 45, the wire hole 46, and the connection wire 47 correspond to the connecting device of the present invention.

Therefore, without using the link mechanism, the frame parts 31-34 can be displaced from the frame 40 to the frame 40a. Here, the frame 40 corresponds to the closed state (the first annular shape state) shown in FIG. 5A, and the frame 40a corresponds to the open state (the second annular shape state) shown in FIG. 5B. Also, in contrast, when the frame parts 31-34 are to be displaced from the frame 40a to the frame 40, the frame parts 31-34 are easily displaced to the closed state (the frame 40) by pulling the connection wire 47 radially outwardly relative to the frame 40a. In one embodiment, an opposite end of the connection wire 47 opposite from the end portion 47a may be pulled radially outwardly for easy displacement of the frame parts 31-34. Therefore, the structure can be simplified, and also the operation can be facilitated. Thus, the operation efficiency can be further improved.

Here, in each of the above embodiments, the tape T is held between the front side frame parts 21a-24a, 31a-34a and the back side frame parts 21b-24b, 31b-34b, all of which constitute the frames 20, 30, 40. However, the embodiment is not limited to this structure. For example, as will be explained in a third embodiment and a fourth embodiment, a periphery of the tape T may be fixed to the frame parts by affixing the tape T to the frame parts. Thus, the tape T may not have to have a structure to be held between the frame parts. In this case, the structure of the frame can be simplified.

### Third Embodiment

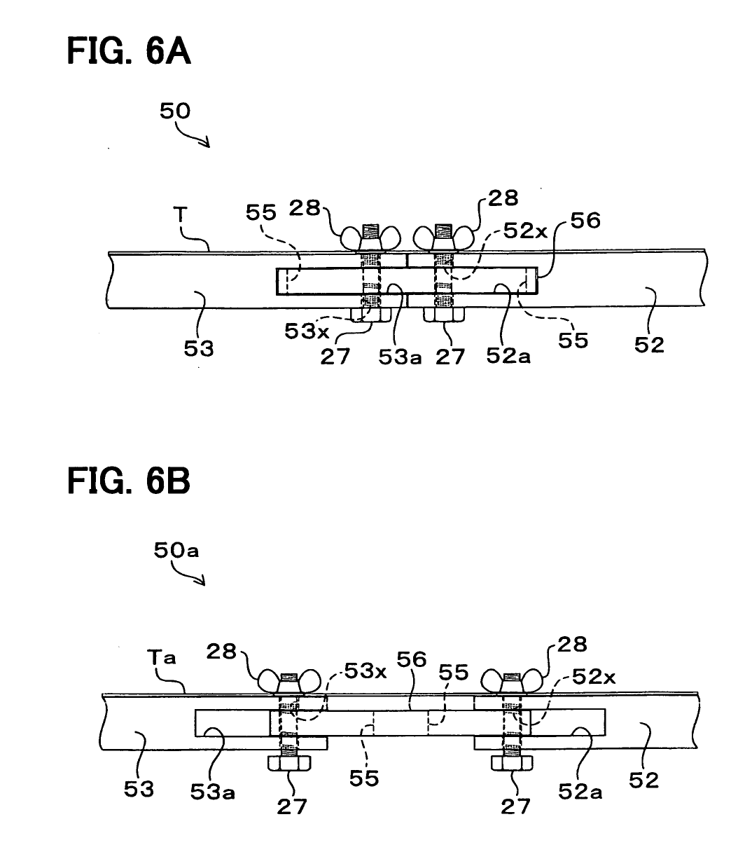

Next, a structure of a frame 50 of the third embodiment will be described with reference to FIGS. 6A and 6B. The frame 50 of the third embodiment differs from the frame 20 of the first embodiment in the following two points. As the first point, the frame 50 includes a fixing plate 56, instead of the links 26 of the frame 20. Here, the fixing plate 56 also serves as the fixing device for the frame 50. As the second point, in the frame 50, the periphery of the tape T is adhered and fixed to the surfaces of frame parts 52, 53. Therefore, components, which are similar to the components of the above frame 20 of the first embodiment, are indicated by the same numerals and explanation thereof will be omitted.

As shown in FIGS. 6A and 6B, the frame 50 of the third embodiment includes polygonal-bar-shaped frame parts 52, 53, a narrow thick fixing plate 56, the bolts 27, and wingnuts 28. The polygonal-bar-shaped frame part 52 includes through grooves 52a, which are relatively long recesses and extend in a longitudinal direction, at both ends thereof. The polygonal-bar-shaped frame part 53 includes through grooves 53a, which are relatively long recesses and extend in a longitudinal direction, at both ends thereof. The narrow thick fixing plate 56 has a shape and a size such that the narrow thick fixing plate 56 extends between the through grooves 52a, 53a and is fitted in the through grooves 52a, 53a. The bolts 27 and the wingnuts 28 are designed to fix the above structure through fastening.

Then, the frame part 52 has threaded holes 52x at both ends thereof such that the corresponding bolt 27 can intersect through the through groove 52a. Also, similar to this, the frame part 53 has threaded holes 53x at both ends thereof such that the corresponding bolt 27 can intersect through the through groove 53a. The fixing plate 56 has elongated holes 55, through each of which the bolt 27 extends in a transverse direction of the fixing plate 56. Also, the bolt 27 is displaceable within the corresponding elongated hole 55 in the longitudinal direction of the fixing plate 56.

Because the frame parts 52, 53 and the fixing plate 56 are structured as above, the fixing plate 56 can be located in the through grooves 52a, 53a of the frame parts 52, 53. Also, the fixing plate 56 and the frame parts 52, 53 can be fastened using the bolts 27 and the wingnuts 28 in a state where the fixing plate 56 is held between the end portions of the frame parts 52, 53.

As shown in FIG. 6A, the frame parts 52, 53, which are connected through the fixing plate 56 serving as the connecting device, are fixed as the frame 50 through the fixing plates 56, the bolts 27, and the wingnuts 28, all of which also serve as the fixing device. Here, the frame 50 corresponds to the first annular shape state (e.g., FIGS. 1A, 4A). The tape T is fixed to the surface of the frame parts 52, 53 by adhering the periphery of the tape T thereto.

Therefore, because the multiple frame parts are kept in the first annular shape (e.g., FIGS. 1A, 4A), an expansion force for radially expanding the wafer W can be applied to the whole surface of the wafer W when the wafer W, which is held by or adhered to the tape T, is upwardly pressed from the back side of the tape T. This process corresponds to the expansion process shown in FIG. 3B. Therefore, variations of a magnitude of the radial expansion force applied to the wafer W can be limited.

In contrast, as shown in FIG. 6B, the frame parts 52, 53, which are connected through the fixing plate 56, the bolts 27, and the wingnuts 28, are released from the fixation by the fixing plates 56, the bolts 27, and the wingnuts 28, all of which serve as the fixing device, when the fixing plate 56, the bolts 27, and the wingnuts 28 are loose in a frame 50a state. The frame 50a state corresponds to the second annular shape state (e.g., shown in FIGS. 1B, 4B).

Here, even in the frame 50a state, which corresponds to the second annular shape state, the frame parts 52, 53 are fixed through the fixing plate 56, the bolts 27, and the wingnuts 28. Thus, the multiple frame parts can be retained as the second annular shape. Thus, the frame parts can be kept in a state where the loose part γ (FIG. 3C), which is expanded to be loose in the expansion process (FIG. 3B), is stretched. Therefore, the tape T is limited from deforming. Thus, the downstream process (e.g., die pick up, the visual inspection) can be facilitated.

### Fourth Embodiment

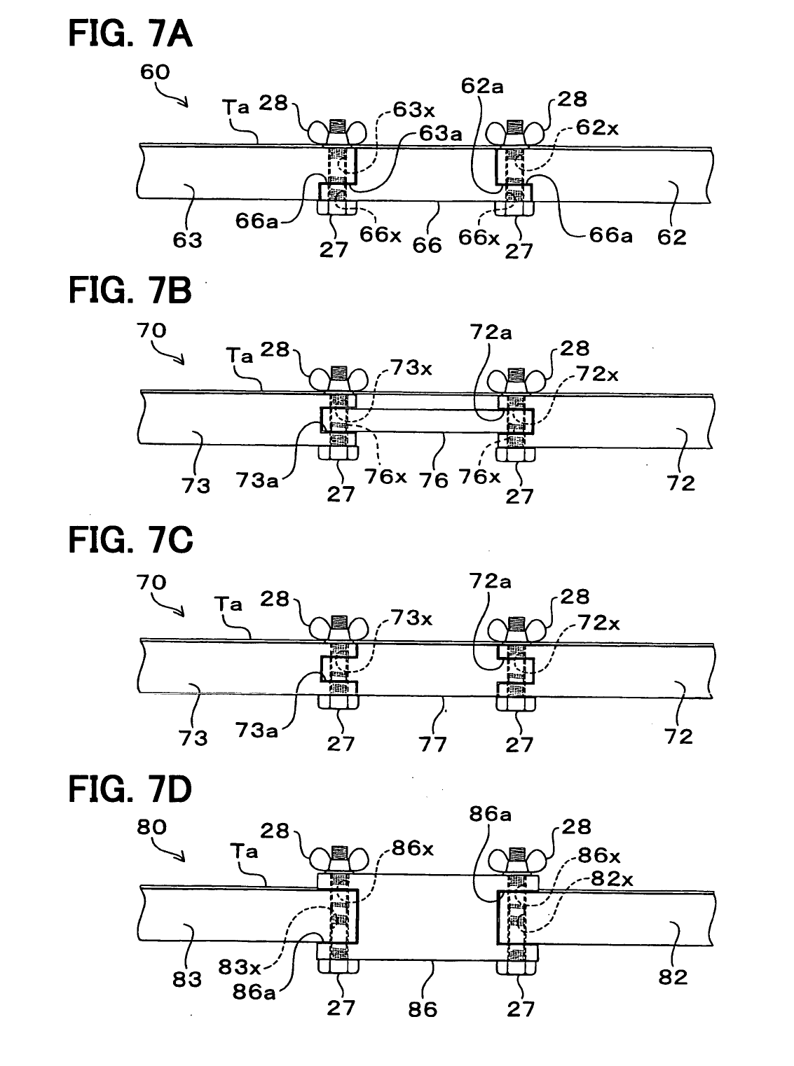

Frames 60, 70, 80 of the fourth embodiment will be described with reference to FIGS. 7A to 7D. The frames 60, 70, 80 of the fourth embodiment differ from the frame 20 of the first embodiment and from the frame 50 of the third embodiment mainly for the following points. The frames 60, 70, 80 do not include the above links 26 of the frame 20. Thus, after the frame of the first annular shape (e.g., FIGS. 1A, 4A) is opened to form the second annular shape (e.g., FIGS. 1B, 4B), the frame is fixed using a fixing jig 66, 67, which serves as the fixing device. Thus, components, which are similar to the components of the above frames 20, 50, are indicated by the same numerals and explanation thereof will be omitted.

As shown in FIG. 7A, a frame 60 of the fourth embodiment includes polygonal-bar-shaped frame parts 62, 63, a fixing jig 66, the bolts 27, and wingnuts 28. The polygonal-bar-shaped frame part 62 includes step grooves 62a at both end portions, each step groove 62a having a step shape and extends in a longitudinal direction. Also, similar to the above, the polygonal-bar-shaped frame part 63 includes step grooves 63a at both end portions, each step groove 63a having a step shape and extends in a longitudinal direction. The fixing jig 66 has a narrow thick plate shape, and includes step grooves 66a at both ends such that the fixing jig 66 extends between the step grooves 62a, 63a to serve as a joint between the step grooves 62a, 63a. The bolts 27 and the wingnuts 28 are designed to fix the above structure through fastening.

The frame part 62 has threaded holes 62x at both ends thereof such that the corresponding bolt 27 extends to intersect the step groove 62a. Also, the frame part 63 has threaded holes 63x at both ends thereof such that the corresponding bolt 27 extends to intersect the step groove 63a. Each step groove 66a, which is assembled to the corresponding one of the step grooves 62a, 63a as the connector, has a threaded hole 66x, which communicates with the corresponding one of the threaded holes 62x, 63x of the frame parts 62, 63.

Thus, the frame parts 62, 63, and the fixing jig 66 are formed such that each step groove 66a of the fixing jib 66 is assembled to the corresponding one of the step grooves 62a, 63a of the frame parts 62, 63. Also, the assembled part between each end portion of the fixing jig 66 and the corresponding one of the frame parts 62, 63 is fastened by the bolts 27 and the wingnuts 28 in a state where the assembled part is pressed.

Therefore, as shown in FIG. 7A, when the adjacent frame parts 62, 63 form the frame 60, which correspond to the second annular shape (large annular shape) (e.g., FIGS. 1B, 4B), the frame parts 62, 63 are fixed using the fixing jig 66, the bolts 27, the wingnuts 28, all serving as the fixing device. Thus, the above multiple frame parts remain in the second annular shape. This results in that the frame parts can be kept in a state where the loose part γ (FIG. 3C), which has been expanded to be loose in the expansion process (FIG. 3B), is stretched. Therefore, the tape T is limited from deforming. Thus, the downstream process (e.g., die pick up, the visual inspection) can be facilitated.

Also, as shown in FIG. 7B, the frame 70 of the fourth embodiment includes polygonal-bar-shaped frame parts 72, 73, a fixing jig 76, the bolts 27, and wingnuts 28. The polygonal-bar-shaped frame part 72 includes through grooves 72a, which are relatively short recesses and extend in a longitudinal direction, at both ends thereof. Similarly, the polygonal-bar-shaped frame part 73 includes through grooves 73a, which are relatively short recesses and extend in the longitudinal direction, at both ends thereof. The fixing jig 76 has a shape and a size such the fixing jig 76 extends between the through grooves 72a, 73a and is fitted in the through grooves 72a, 73a. The bolts 27 and the wingnuts 28 are designed to fix the above structure through fastening.

Then, the frame part 72 has threaded holes 72x for the bolts 27 at ends thereof, such that the corresponding bolt 27 can intersect through the through groove 72a. Also, similar to this, the frame part 73 has threaded holes 73x for the bolts 27 at ends thereof, such that the corresponding bolt 27 can intersect through the through groove 73a. Each end of the fixing jig 76, which end is assembled to the corresponding one of the through grooves 72a, 73a as the joint, has a threaded hole 76x for the bolt, which communicates with the corresponding one of the threaded holes 72x, 73x of the frame parts 72, 73.

The frame parts 72, 73 and the fixing jig 76 are structured as above such that the fixing jig 76 can be located in the through grooves 72a, 73a of the frame parts 72, 73. Also, the fixing jig 76 can be assembled to the frame parts 72, 73 through a bar joint. Also, the fixing jig 76 and the frame parts 72, 73 are fastened using the bolts 27 and the wingnuts 28 in a state where each end portion of the fixing jig 76 is held between the corresponding one of the end portions of the frame parts 72, 73.

Therefore, as shown in FIG. 7B, when the adjacent frame parts 72, 73 form the frame 70, which correspond to the second annular shape (e.g., FIGS. 1B, 4B), the frame parts 72, 73 are fixed using the fixing jig 76, the bolts 27, the wingnuts 28, all serving as the fixing device. Thus, the above multiple frame parts remain in the second annular shape. This results in that the frame parts can be kept in a state, where the loose part γ (FIG. 3C), which has been expanded to be loose in the expansion process (FIG. 3B), is stretched. Therefore, the tape T is limited from deforming. Thus, the downstream process (e.g., die pick up, the visual inspection) can be facilitated.

Here, as shown in FIG. 7C, a fixing jig 77 may have a width similar to that of the frame parts 72, 73 such that each end of the fixing jig 77 and the corresponding one of the end portion of the frame parts 72, 73 can be assembled as a tongue-and-groove-joint. Thus, connections between the fixing jig 77 and each of the frame parts 72, 73 can be more reliably fixed.

Also, as shown in FIG. 7D, frame parts 82, 83 may not have through grooves at end portions. Thus, a fixing jig 86 may be designed to cover the end portions. That is, the frame 80 of the fourth embodiment shown in FIG. 7D has the fixing jig 86, which is formed to have an H-shape in a vertical section such that the fixing jig 86 has through grooves 86a at both ends thereof. Here, the through grooves 86a are recesses. Then, the fixing jig 86 has a threaded hole 86x at each end thereof such that the bolt 27 can intersect through the corresponding one of the through grooves 86a. An end of the frame part 82 is assembled to the corresponding through groove 86a as a joint, and the frame part 82 has a threaded hole 82x at the end such that the threaded hole 82x communicates with the corresponding threaded hole 86x. Similar to this, an end of the frame part 83 is assembled to the corresponding through groove 86a as a joint, and the frame part 83 has a threaded hole 83x at the end such that the threaded hole 83x communicates with the corresponding threaded hole 86x.

The frame parts 82, 83, and the fixing jig 86 are formed as above such that each end of the frame parts 82, 83 is located in the corresponding one of the through grooves 86a of the fixing jig 86. Thus, the frame parts 82, 83, and the fixing jig 86 can be assembled as a plate-joint. Also, the frame parts 82, 83, and the fixing jig 86 are fastened using the bolts 27 and the wingnuts 28 in a state, where each of the end portions of the frame parts 82, 83 is held (received) by the corresponding end portion of the fixing jig 86.

Therefore, as shown in FIG. 7D, when the adjacent frame parts 82, 83 form the frame 80, which correspond to the second annular shape (e.g., FIGS. 1B, 4B), the frame parts 82, 83 are fixed using the fixing jig 86, the bolts 27, the wingnuts 28, all serving as the fixing device. Thus, the above multiple frame parts remain in the second annular shape. This results in that the frame parts can be kept in a state, where the loose part γ (FIG. 3C), which has been expanded to be loose in the expansion process (FIG. 3B), is stretched. Therefore, the tape T is limited from deforming. Thus, the downstream process (e.g., die pick up, the visual inspection) can be facilitated.

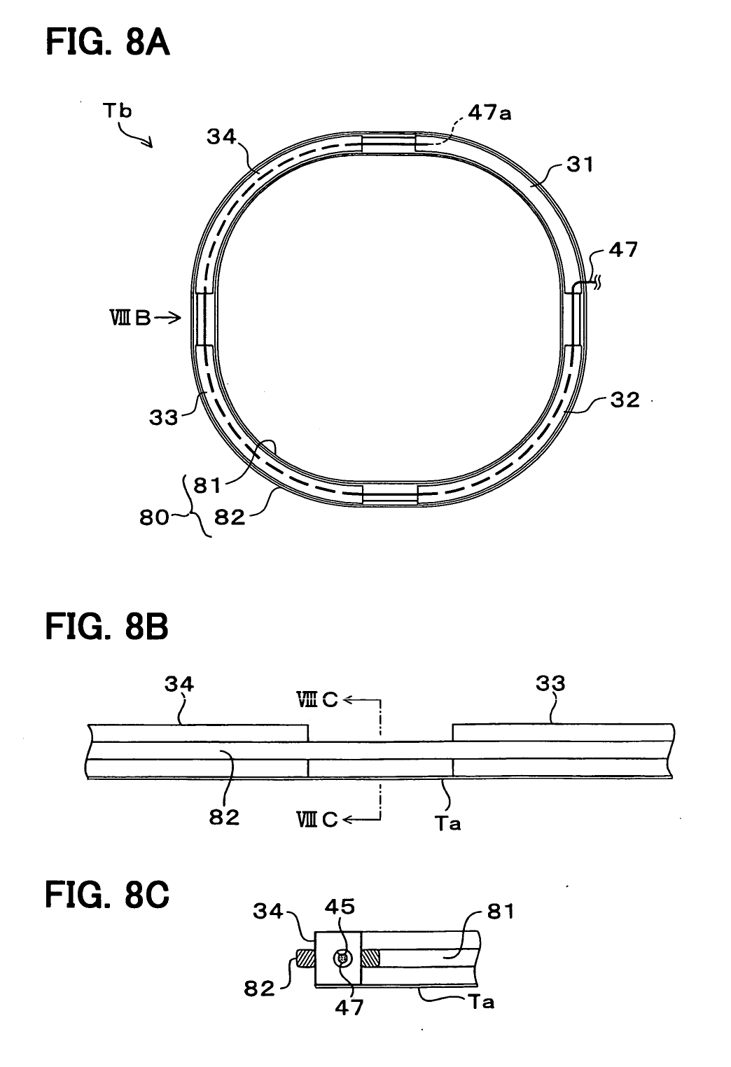

The above frame 40 of the second embodiment is designed without the link mechanism (the elongated holes 25, the links 26, the bolts 27, and the wingnuts 28) as the connecting device. However, an example of the frame 40, which has the fixing device, will be described with reference to FIGS. 8A to 8C.

As shown in FIGS. 8A to 8C, a fixing jig 80 serving as the fixing device includes an annular wire 81 (first fixing device) and an annular wire (second fixing device) 82. The annular wire 81 expands radially outwardly such that the diameter thereof increases. The annular wire 82 contracts radially inwardly such that a diameter thereof decreases. The annular wire 81 is a resilient metallic wire, which has a generally rectangle sectional shape, and has an annular shape of a diameter larger than an inner diameter of a frame 40b, which is in the second annular shape state (e.g., FIG. 5B). The annular wire 82 is also a resilient metallic wire, which has a generally rectangle sectional shape, and has an annular shape of a diameter smaller than an outer diameter of the frame 40b, which is in the second annular shape state (e.g., FIG. 5B).

Also, the annular wires 81, 82 are both made of the same resilient wire. Therefore, an expansion force of the annular wire 81, which expands radially outwardly, is designed to be generally equal to a contraction force of the annular wire 82, which contracts radially inwardly.

The fixing jig 80, having the two annular wires 81, 82, is provided to the frame 40b, which is in the second annular shape state (e.g., FIG. 5B). Specifically, the annular wires 81, 82 are, respectively, placed at a radially inner face and a radially outer face of the frame 40b. Thus, the annular wire 81 radially outwardly presses the frame 40b from the radially inner face thereof. In contrast, the annular wire 82 radially inwardly presses the frame 40b from the radially outer face thereof. Here, because the spring forces of both the annular wires 81, 82 are generally equal to each other as discussed above, it becomes possible that the frame 40b is kept in the second annular shape state (e.g., FIGS. 1B, 4B) in a state, where the frame 40b is held between the annular wire 81 and the annular wire 82.

As above, the fixing jig 80, which has the two annular wires 81, 82, can fix the frame 40 without modifying the frame 40. Thus, a machining work hour or the number of components can be effectively reduced. Also, by changing the annular shape of the annular wire depending on the shape of the frame, the various fixing jigs can be easily realized.

Additional advantages and modifications will readily occur to those skilled in the art. The invention in its broader terms is therefore not limited to the specific details, representative apparatus, and illustrative examples shown and described.

What is claimed is:

1. A dicing sheet frame, which is used when a semiconductor wafer adhered to a dicing sheet is cut into chips, the dicing sheet frame comprising:
a plurality of frame parts that supports the dicing sheet; and
a connecting device that connects the plurality of frame parts such that the plurality of frame parts has an annular shape.

2. The dicing sheet frame according to claim 1, wherein:
the connecting device that connects the plurality of frame parts such that the plurality of frame parts has a first annular shape as the annular shape, the first annular shape surrounding a first area larger than an adhesion area, to which the semiconductor wafer is adhered; and
the plurality of frame parts is displaceable to have a second annular shape, which surrounds a second area larger than the first area.

3. The dicing sheet frame according to claim 2, wherein:
each of the plurality of frame parts has a corresponding one of a plurality of divided shapes, into which the first annular shape is divided.

4. The dicing sheet frame according to claim 2, wherein:
the first annular shape includes a generally circular shape.

5. The dicing sheet frame according to claim 2, wherein:
the connecting device serves as a fixing device that fixes adjacent ones of the plurality of frame parts, which are connected by the connecting device; and
the plurality of frame parts are fixed by the fixing device in a state, where the plurality of frame parts has the first annular shape.

6. The dicing sheet frame according to claim 2, wherein:
the connecting device serves as a fixing device that fixes adjacent ones of the plurality of frame parts, which are connected by the connecting device; and
the plurality of frame parts are fixed by the fixing device in a state, where the plurality of frame parts has the second annular shape.

7. The dicing sheet frame according to claim 1, wherein:
the dicing sheet is adhered to the plurality of frame parts to be supported by the plurality of frame parts.

8. The dicing sheet frame according to claim 2, further comprising a fixing device that fixes the plurality of frame parts, which are connected by the connecting device, in a state where the plurality of frame parts has the second annular shape, wherein the fixing device includes:
a first fixing device that is provided on a radially inner side of the plurality of frame parts; and
a second fixing device that is provided on a radially outer side of the plurality of frame parts.

9. The dicing sheet frame according to claim 1, wherein:
the annular shape is a large annular shape that surrounds a large area;
each of the plurality of frame parts has a corresponding one of a plurality of divided shapes, into which a small annular shape is divided; and
the small annular shape surrounds a small area that is smaller than the large area and is larger than an adhesion area, to which the semiconductor wafer is adhered.

10. The dicing sheet frame according to claim 9, wherein:
the connecting device serves as a fixing device that fixes adjacent ones of the plurality of frame parts, which are connected by the connecting device; and
the plurality of frame parts are fixed by the fixing device in a state, where the plurality of frame parts has the large annular shape.
